(19) United States
(12) Patent Application Publication
(10) Pub. No.: US 2025/0246860 A1
(43) Pub. Date: Jul. 31, 2025

(54) COMPOSITE CONNECTOR

(71) Applicant: EMPASS TECHNOLOGY INC., New Taipei City (TW)

(72) Inventors: Yang-Chih Huang, New Taipei City (TW); Chi-Kai Shen, New Taipei City (TW); Yu-Hao Cheng, New Taipei City (TW)

(21) Appl. No.: 19/034,595

(22) Filed: Jan. 23, 2025

(30) Foreign Application Priority Data
Jan. 29, 2024 (TW) 113103341

(51) Int. Cl. H01R 13/719; H01R 12/71

(52) U.S. Cl. CPC H01R 13/719; H01R 12/716

(57) ABSTRACT

A composite connector incudes a connector, a carrier circuit board, and a plurality of filtering units. The connector is disposed on at least one surface of the carrier circuit board, and multiple connection pins are disposed on at least one surface of the carrier circuit board. The carrier circuit board is disposed on a main circuit board or a main circuit board connector of the main circuit board. The filtering units are disposed on the carrier circuit board and connected to part or all of the connection pins to filter out noise on the connection pins. The composite connector of the invention can have a filtering function, thereby reducing the manufacturing cost of electronic devices and increasing the routing flexibility of the main circuit board.

### CROSS-REFERENCE TO RELATED APPLICATIONS

This non-provisional application claims priority claim under 35 U.S.C. § 119(a) on Taiwan Patent Application No. 113103341 filed Jan. 29, 2024, the entire contents of which are incorporated herein by reference.

### TECHNICAL FIELD

This invention is a composite connector, which is advantageous for reducing the manufacturing cost of electronic devices and increasing the routing flexibility of the main circuit board.

### BACKGROUND

Motherboard is one of the primary components of a computer or electronic device, serving as a platform for multiple expansion cards to connect and communicate with each other.

As shown in FIG. 1, various types of connectors 13 can be configured on the surface of the motherboard 11. Expansion cards can be inserted into these connectors 13 to establish electrical connections between the expansion cards and the motherboard 11.

Specifically, the connector 13 includes a slot 133, which is used to connect the expansion card. Additionally, the connector 13 is provided with a plurality of pins 131, typically located within or near the slot 133, and used to connect to pins on the expansion card. The pins 131 extend from the slot 133 of connector 13 to the bottom, wherein the exposed pins 131 on the bottom can be defined as connection pins 135.

Multiple connection holes 111 or metal pads are provided on the motherboard 11. The connection pins 135 of the connector 13 can be inserted into the connection holes 111 of the motherboard 11 and then soldered in place to secure the connector 13 to the motherboard 11.

The connector 13 is used to connect the motherboard 11 and the expansion card, and the connection interface of the expansion card can be inserted into the slot 133 of connector 13 to contact with pins 131. The motherboard 11 can provide power to the expansion card through connector 13, while the expansion card can transmit signals to and from the motherboard 11 or other expansion cards or chips disposed on the motherboard.

### SUMMARY

Traditional connectors provide only signal transmission and power supply functions. If additional signal processing or filtering is required, extra filtering units or processing components must be disposed on the motherboard or mainboard. To enhance the functionality and value of connectors and reduce the complexity and area of motherboards or mainboards, this invention proposes a novel composite connector.

This invention provides a composite connector, which comprising a connector mounted on a carrier circuit board. Additional components, such as filtering units, are disposed on the carrier circuit board to expand the capabilities of the composite connector. The connector and filtering units may be located on or on one side of the carrier circuit board. The carrier circuit board is mounted on or on one side of a main circuit board. This arrangement allows the composite connector to perform filtering functions. Alternatively, the connector and the main circuit board may be disposed on the same side of the carrier circuit board.

The filtering function typically refers to the process where signals of different frequencies experience different gains or attenuations as they pass through a filtering unit, allowing for the retention of specific frequency components. In some cases, filtering units may provide different delays or phase shifts for signals of different frequencies, thus allowing for signal adjustment. Common types of filtering units include low-pass, high-pass, band-pass, and band-stop filters, which can be distinguished by their DC and high-frequency frequency responses. A low-pass filter allows DC or low-frequency signals to pass through with minimal attenuation, and the attenuation generally increases with increasing frequency, except for specially designed responses such as Chebyshev filters. A high-pass filter significantly attenuates or completely blocks DC signals, and the attenuation generally decreases with increasing frequency, except for specially designed responses such as Chebyshev filters. A band-pass filter allows signals within a specific frequency range to pass through with minimal attenuation, while significantly attenuating or blocking DC and high-frequency signals. A band-stop filter significantly attenuates or completely blocks signals within a specific frequency range, while allowing DC and high-frequency signals to pass through with relatively lower attenuation.

In some special applications, multiple transmission lines may be used to transmit signals, thereby mitigating external noise interference and reducing radiation from the device itself. In such systems, signals may be transmitted in various modes. However, in many applications, the mode where all transmission lines transmit signals in-phase tends to generate radiation and is thus often considered noise, known as common-mode noise. In this invention, the suppression of common-mode noise at specific frequencies is a design goal for filtering units.

The connector of the composite connector may be a standard, general-purpose connector, compatible with expansion cards or devices having a corresponding interface. Additionally, the connection pins of the carrier circuit board in the composite connector may be identical to those of a standard, general-purpose connector and thus can be connected to the transmission lines of a main circuit board. In another embodiment of the invention, the composite connector of this invention may share pins with a common standard connector. This allows for the addition of new functionalities to the electronic product without significantly increasing or even without increasing the complexity of the main circuit board, thereby saving design time.

To achieve the foregoing objectives, this disclosure provides a composite connector, which comprises a connector, a carrier circuit board, a plurality of first connection pins, a plurality of second connection pins and at least one filtering unit. The connector is configured to connect to an expansion card or an expansion device, and includes a plurality of pins. The carrier circuit board includes a plurality of surfaces and a plurality of transmission paths. The first connection pins are disposed on at least one of the surfaces of the carrier circuit board, and are connected to the pins of the connector and the transmission paths of the carrier circuit board. The second connection pins are disposed on at least one of the surfaces of the carrier circuit board, and are configured to connect to a plurality of transmission lines of a main circuit board and the transmission paths of the carrier circuit board. The filtering unit is disposed on the carrier circuit board, wherein part or all of the transmission paths on the carrier circuit board are connected to the filtering unit.

This disclosure provides another composite connector, which comprises a connector, a carrier circuit board, a plurality of first connection pins, a plurality of second connection pins and at least one filtering unit. The connector is used to connect to an expansion card or an expansion device, and includes a plurality of pins. The carrier circuit board is disposed inside the connector and includes a plurality of surfaces and a plurality of transmission paths. The first connection pins are disposed on at least one of the surfaces of the carrier circuit board, and are connected to the pins of the connector and the transmission paths of the carrier circuit board. The second connection pins are disposed on at least one of the surfaces of the carrier circuit board, and are connected to part of the pins of the connector and the transmission paths of the carrier circuit board. The filtering unit is disposed on the carrier circuit board, wherein part or all of the transmission paths on the carrier circuit board are connected to the filtering unit.

This disclosure provides another composite connector, which comprises a first connector, a carrier circuit board, a plurality of first connection pins, a second connector and at least one filtering unit. The first connector is used to connect to an expansion card or an expansion device, and includes a plurality of first pins. The carrier circuit board includes a plurality of surfaces and a plurality of transmission paths. The first connection pins are disposed on at least one of the surfaces of the carrier circuit board, and are connected to the first pins of the first connector and the transmission paths of the carrier circuit board. The second connection pins are disposed on at least one of the surfaces of the carrier circuit board. The second connector includes a plurality of second pins for connecting to the second connection pins of the carrier circuit board and a plurality of transmission lines of a main circuit board. The filtering unit is disposed on the carrier circuit board, wherein part or all of the transmission paths on the carrier circuit board are connected to the filtering unit.

### BRIEF DESCRIPTION OF THE DRAWINGS

FIG. 1 is an exploded perspective view of a conventional connector.

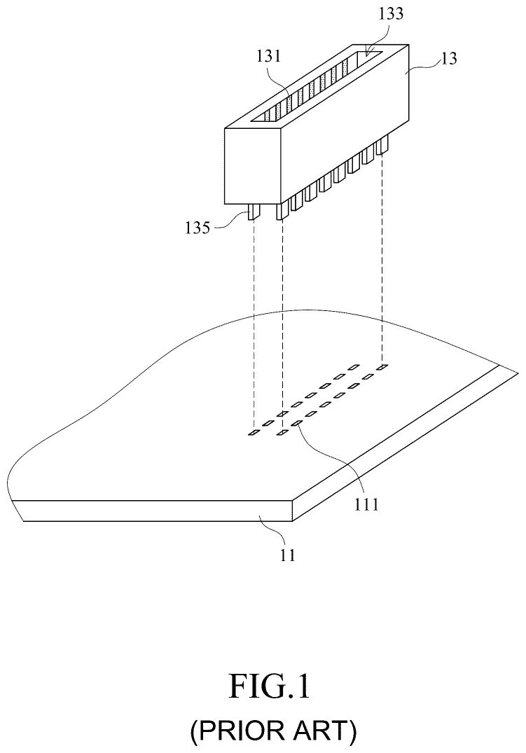

FIG. 2 is a front view exploded perspective diagram of a composite connector according to an embodiment of the invention.

FIG. 3 is a bottom view perspective diagram of a composite connector according to an embodiment of the invention.

FIG. 4 is a perspective view of an electronic device according to an embodiment of the invention.

FIG. 5 is an exploded perspective view of a composite connector according to another embodiment of the invention.

FIG. 6 is a perspective view of a composite connector according to another embodiment of the invention.

FIG. 7 is an exploded perspective view of an electronic device according to another embodiment of the invention.

FIG. 8 is an exploded perspective view of an electronic device according to another embodiment of the invention.

FIG. 9 is an exploded perspective view of a composite connector according to another embodiment of the invention.

FIG. 10 is an exploded perspective view of a composite connector according to another embodiment of the invention.

### DETAILED DESCRIPTION

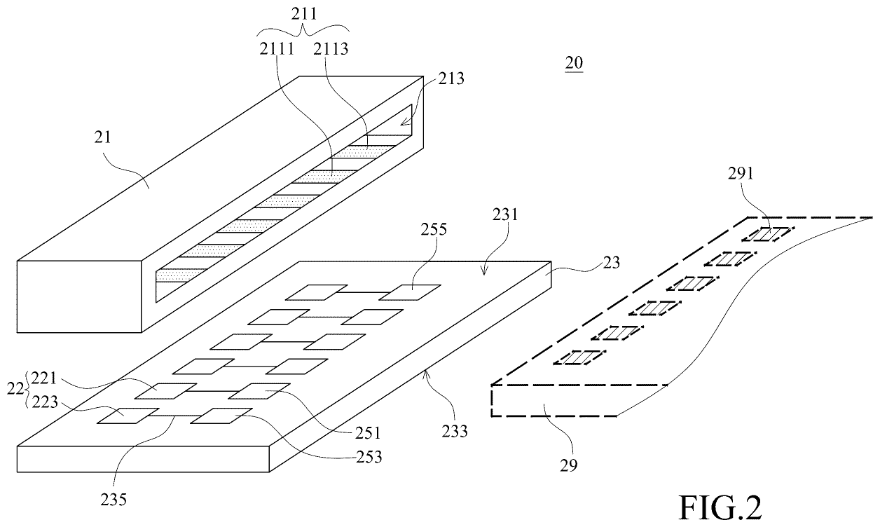

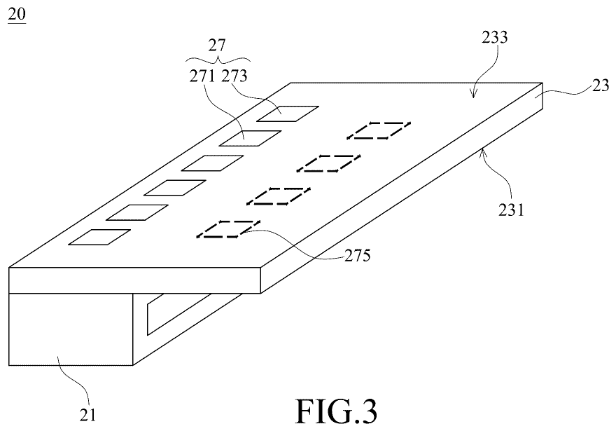

FIG. 2 is a front view exploded perspective diagram of a composite connector according to an embodiment of the invention. FIG. 3 is a bottom view perspective diagram of a composite connector according to an embodiment of the invention. The composite connector 20 includes a connector 21, a carrier circuit board 23, a plurality of filtering units 251, a plurality of first connection pins 22, and a plurality of second connection pins 27. The connector 21, first connection pins 22, filtering units 251, and second connection pins 27 are disposed on the carrier circuit board 23.

The connector 21 is conventionally used to connect expansion cards or expansion devices. Its primary functions are signal transmission and power supply, and it does not have additional capabilities. For instance, in order to filter signals transmitted between an expansion card and a motherboard, multiple filtering units are disposed on a motherboard, allowing the expansion card or expansion device to connect to transmission lines on the motherboard through the filtering units.

Placing multiple filtering units on the motherboard, while effective in filtering signals between the motherboard and expansion cards, often results in these units occupying valuable surface area on the motherboard. Motherboards are typically multi-layer circuit boards. The filtering units disposed on the surface of the motherboard require connecting the inner-layer traces of the motherboard, which increases manufacturing complexity and restricts the flexibility of circuit layout of the motherboard. Additionally, placing a large number of filtering units on the motherboard undoubtedly increases both the manufacturing cost and time. For instance, soldering a significant number of filtering units onto the motherboard is a time-consuming and costly process.

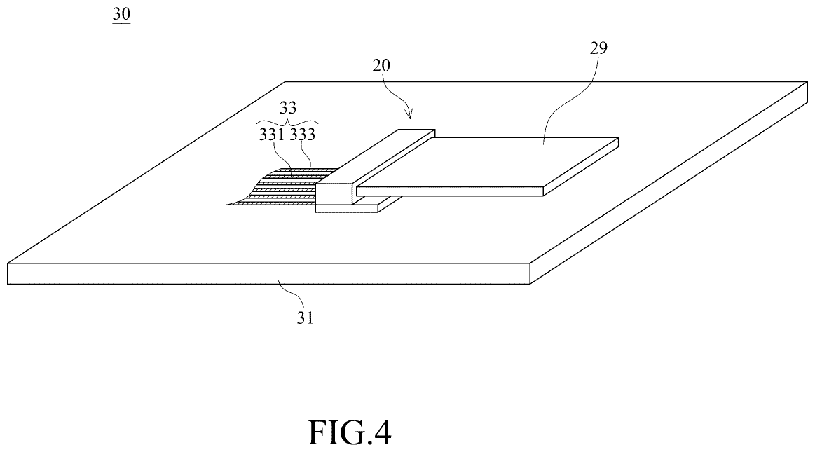

To address the aforementioned problems, this invention proposes a composite connector 20. The connector 21 is disposed on the carrier circuit board 23, and multiple filtering units 251 are disposed on the carrier circuit board 23. This design enables the composite connector 20 to provide filtering functionality. For example, the filtering units 215 may include at least one band-stop filter or at least one band-pass filter. Additionally, the filtering units 251 can be used to block or absorb common-mode noise at specific frequencies. As shown in FIG. 4, by simply installing the composite connector 20 onto the main circuit board 31, the composite connector 20 can perform the filtering function. This eliminates the need for disposing the filtering units 251 on the surface of the main circuit board 31, significantly reducing manufacturing complexity and costs.

The main circuit board 31 described in this invention may be a motherboard or a daughterboard of a computer or electronic device, which is typically a multilayer circuit board. The carrier circuit board 23 described in this invention may have fewer layers than the main circuit board 31, such as being a single-layer or double-layer circuit board. Therefore, integrating the filtering units 251 onto the carrier circuit board 23 is significantly less difficult and costly compared to placing them on the main circuit board 31.

In one embodiment of the invention, the carrier circuit board 23 may be a planar board including a first surface 231 and a second surface 233. The first connection pins 22 are disposed on the first surface 231 of the carrier circuit board 23, while the second connection pins 27 are disposed on the second surface 233 of the carrier circuit board 23. The connector 21 is disposed on the first surface 231 of the carrier circuit board 23 and is connected to the first connection pins 22 located on the first surface 231. For example, the first surface 231 and the second surface 233 may be the top surface and the bottom surface of the carrier circuit board 23, respectively. However, it should be noted that the first surface 231 and the second surface 233 being opposite surfaces of the carrier circuit board 23 is merely an embodiment of the invention and is not limitation of the invention.

The connector 21 described in this invention may be a common slot or connector found on general-purpose motherboards or electronic devices, and is used to connect an expansion card 29 or an expansion device 49. For examples, the connector 21 includes, but are not limited to, PCI, PCI Express, IDE, SATA, eSATA, USB, M.2, RJ-45, DVI, HDMI, SCSI, SAS, and U.2.

Specifically, the connector 21 may include a slot 213, and multiple pins 211 are disposed within the slot 213. The pins 211 extend from the slot 213 to the exterior of the connector 21 and are used to connect to the first connection pins 22 on the carrier circuit board 23. In practical applications, an expansion card 29 can be inserted into the slot 213 of the connector 21, such that the connection interface 291 on the expansion card 29 is connected to the pins 211 within the slot 213. For example, the expansion card 29 may include, but is not limited to, a hard disk drive, a solid-state drive, a network card, a memory module, a network transformer, a graphics card, and a sound card.

The carrier circuit board 23 includes a plurality of transmission paths 235. The first connection pins 22 are connected to the transmission paths 235, and are connected to the second connection pins 27 via the transmission paths 235. For example, the transmission paths 235 may be transmission lines or conduction lines disposed on the surface and/or inside the carrier circuit board 23.

In one embodiment of the invention, the number of the first connection pins 22 and the second connection pins 27 on the carrier circuit board 23 may be the same as the number of the pins 211 of the connector 21. The first connection pins 22 and the second connection pins 27 have the same specifications as the pins 211 of the connector 21 and are respectively connected to the individual pins 211 of the connector 21. For example, the first connection pins 22 and the second connection pins 27 may include, but are not limited to, land grid array (LGA), pin grid array (PGA), and ball grid array (BGA) packages.

Therefore, when the composite connector 20 of the invention is disposed on the main circuit board 31, there is no need to make any special changes to the specifications of the main circuit board 31. Specifically, the main circuit board 31 that can be used to connect the conventional connector 13 can also be used to connect the composite connector 20 described in the invention. Furthermore, for the convenience of illustration, the filtering unit 251, the power filtering unit 253, and the signal delay structure 255 are all shown in FIG. 2, but in practical applications, the carrier circuit board 23 may only be equipped with the filtering unit 251, without the power filtering unit 253 and the signal delay structure 255.

In another embodiment of the invention, as shown in FIG. 3, the carrier circuit board 23 of the composite connector 20 may include at least one additional connection pin 275. The composite connector 20 having the additional connection pin 275 can be used to connect the conventional main circuit board 31, in which case the additional connection pin 275 will not provide any additional functionality. Conversely, when the composite connector 20 having the additional connection pin 275 is connected to a main circuit board 31 with special specifications, such as a main circuit board 31 having a transmission line corresponding to the additional connection pin 275, the functionality of the composite connector 20 can be enhanced through the additional connection pin 275. In other words, the composite connector 20 having the additional connection pin 275 can be used as a conventional connector or as a connector with special specifications.

A plurality of filtering units 251 are disposed on the carrier circuit board 23, such as the first surface 231 of the carrier circuit board 23, and thus the filtering units 251 and the connector 21 are located on the same surface of the carrier circuit board 23. The arrangement of the filtering units 251 on the first surface 231 of the carrier circuit board 23 and the connector 21 on the same surface of the carrier circuit board 23 is an embodiment of the invention and is not limitation of the invention.

In one embodiment of the invention, the filtering unit 251 may be disposed inside the carrier circuit board 23. For example, when the carrier circuit board 23 is a multilayer circuit board, the filtering unit 251 may be disposed on an inner layer of the carrier circuit board 23. In one embodiment of the invention, the filtering unit 251 may be at least one metal layer and located on the surface or inside the carrier circuit board 23, such as a metal pattern of a specific shape formed by the metal layer.

During the manufacturing process of the carrier circuit board 23, the filtering units 251 may be fabricated on the inner layer of the carrier circuit board 23 through an etching process. The filtering units 251 may be a passive component, such as a capacitor, an inductor, a differential transmission line, or a common-mode noise suppression circuit, thereby eliminating the manufacturing steps and costs associated with surface-mounting the filtering units 251 onto the carrier circuit board 23.

Specifically, the filtering units 251 may be connected to part or all of the transmission paths 235, and the filtering units 251 are located between the pins 211 of the connector 21 and the second connection pins 27 of the carrier circuit board 23. In one embodiment of the invention, the number of filtering units 251 may be equal to the number of pins 211 of the connector 21 and the first connection pins 22, transmission paths 235, and/or second connection pins 27 of the carrier circuit board 23, with a filtering unit 251 being provided between each pin 211 and each second connection pin 27. In another embodiment, the number of filtering units 251 may be less than the number of pins 211 of the connector 21 and the first connection pins 22, transmission paths 235, and/or second connection pins 27 of the carrier circuit board 23, with filtering units 251 being provided between only a portion of the pins 211 and a portion of the second connection pins 27.

In practical applications, the pins 211 of the connector 21 may include a plurality of signal pins 2111 and at least one power pin 2113. The first connection pins 22 of the carrier circuit board 23 may include a plurality of signal connection pins 221 and at least one power connection pin 223. The second connection pins 27 of the carrier circuit board 23 may include a plurality of signal connection pins 271 and at least one power connection pin 273. The transmission line 33 of the main circuit board 31 may include a plurality of signal transmission lines 331 and at least one power transmission line 333.

The pins 211 of the connector 21 are connected to the transmission line 33 of the main circuit board 31 via the second connection pins 27 of the carrier circuit board 23. Specifically, the signal pins 2111 of the connector 21 are connected to the signal transmission lines 331 of the main circuit board 31 via the signal connection pins 271 of the carrier circuit board 23, while the power pin 2113 of the connector 21 is connected to the power transmission line 333 of the main circuit board 31 via the power connection pins 223/273 of the carrier circuit board 23.

The filtering unit 251 is used to filter noise or suppress common-mode noise on the transmission lines 33, the first connection pins 22, the transmission paths 235, the second connection pins 27, and/or the pins 211. For example, the filtering unit 251 may include, but is not limited to, capacitors, inductors, diodes, transistors, differential transmission lines, or common-mode noise suppression circuits.

In another embodiment of the invention, power filtering units 253 may be provided between the plurality of power pins 2113 and the plurality of power connection pins 273, providing a stable voltage under varying power supply or load current conditions. For example, the power filtering units 253 may include, but are not limited to, capacitors, inductors, diodes, or transistors. In one embodiment of the invention, the power filtering units 253 may be disposed inside the carrier circuit board 23. For example, when the carrier circuit board 23 is a multilayer circuit board, the power filtering units 253 can be fabricated on an inner layer of the carrier circuit board 23 through an etching process.

Specifically, the power filtering units 253 can be used to suppress power noise in specific frequency bands or with specific characteristics, thereby reducing interference from the power supply to neighboring signals or powered electronic components under certain frequency bands or conditions. For example, the power filtering units 253 may include, but is not limited to, capacitors or inductors. In one embodiment of the invention, the power filtering units 253 may be disposed inside the carrier circuit board 23. For example, when the carrier circuit board 23 is a multilayer circuit board, the power filtering units 253 can be fabricated on the inner layer of the carrier circuit board 23 through an etching process.

When the filtering unit 251 or the power filtering unit 253 is disposed on the surface of the carrier circuit board 23 through soldering, such as when the filtering unit 251 and the power filtering unit 253 are capacitors or inductors, the user can replace the capacitors or inductors disposed on the carrier circuit board 23 according to the required filtering or voltage regulation capability of the composite connector 20.

In this way, manufacturers can produce a large quantity of composite connectors 20 with the same specifications, and then dispose capacitors or inductors on the carrier circuit board 23 according to the needs of the product. This allows the same specification of composite connector 20 to be applied to different main circuit boards 31, effectively reducing the inventory pressure and production costs of the manufacturer.

In one embodiment of the invention, as shown in FIG. 2, the carrier circuit board 23 includes at least one signal delay structure 255, such as a transmission line of a specific length or a reactive load. In practical applications, the signal delay structure 255 can be arranged on the transmission path 235 that is not connected to the filtering unit 251, and is located between the first connection pins 22 and the second connection pins 27, so that the signals passing through the filtering unit 251 and those not passing through the filtering unit 251 can be synchronized between the first connection pins 22 and the second connection pins 27.

FIG. 4 is a perspective view of an electronic device according to an embodiment of the invention. Please referring to FIG. 2 and FIG. 3, the electronic device 30 includes a main circuit board 31 and at least one composite connector 20. A plurality of transmission lines 33 are disposed on the surface of the main circuit board 31, and the composite connector 20 disposed on the surface of the main circuit board 31 is electrically connected to the transmission lines 33.

In one embodiment of the invention, the carrier circuit board 23 of the composite connector 20 is disposed on the surface of the main circuit board 31, wherein the carrier circuit board 23 is located between the connector 21 and the main circuit board 31. The second connection pins 27 of the carrier circuit board 23 are respectively connected to the transmission lines 33 of the main circuit board 31, allowing the expansion card 29 plugged into the composite connector 20 to transmit signals and power with the main circuit board 31.

In one embodiment of the invention, a plurality of filtering units 251 and/or power filtering units 253 are disposed on the carrier circuit board 23 of the composite connector 20. The composite connector 20 only needs to be disposed on the main circuit board 31, and the filtering unit 251 on the composite connector 20 can be used to filter the signals transmitted between the main circuit board 31 and the expansion card 29, while the power filtering unit 253 on the composite connector 20 can be used to regulate the power supplied by the main circuit board 31 to the expansion card 29.

In one embodiment of the invention, the main circuit board 31 may be a motherboard or a daughterboard of a computer or an electronic device. Since the main circuit board 31 has more complex functions and may need to connect to many different expansion cards 29 or expansion devices, the complexity of the wiring on the main circuit board 31 is quite high. By using the composite connector 20, the filtering unit 251 and/or the power filtering unit 253 can be disposed on the carrier circuit board 23 with simpler wiring, eliminating the need to install the filtering unit 251 and/or the power filtering unit 253 on the surface of the main circuit board 31. Therefore, it can significantly reduce the difficulty and process of installing the filtering unit 251 and/or the power filtering unit 253, and it is beneficial to improve the freedom of wiring on the main circuit board 31.

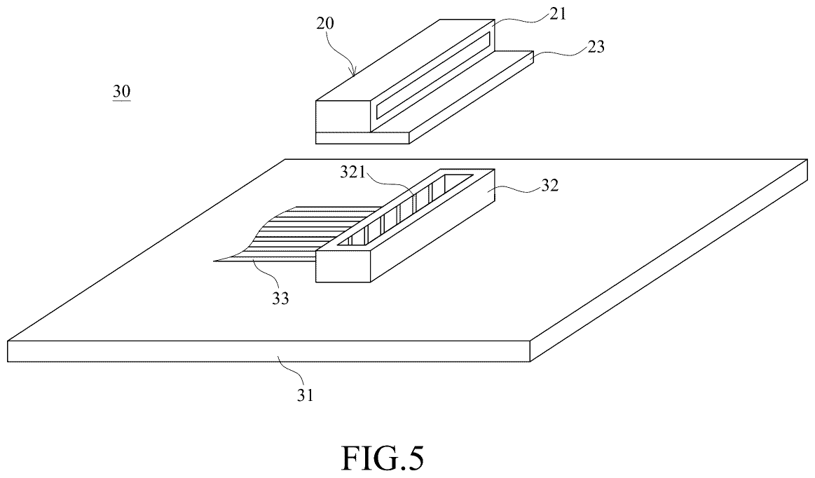

In one embodiment of the invention, the carrier circuit board 23 of the composite connector 20 is directly mounted on the main circuit board 31, replacing the connector seat that was originally installed on the carrier circuit board 23. In another embodiment, as shown in FIG. 5, the carrier circuit board 23 of the composite connector 20 is disposed on a main circuit board connector 32 of the main circuit board 31.

Specifically, the main circuit board 31 can be equipped with a conventional main circuit board connector 32, and the pins 211 of the connector 21 of the composite connector 20 can be directly connected to the pins 321 of the main circuit board connector 32 on the main circuit board 31, allowing the multiple transmission lines 33 of the main circuit board 31 to connect to the transmission path 235 of the carrier circuit board 23.

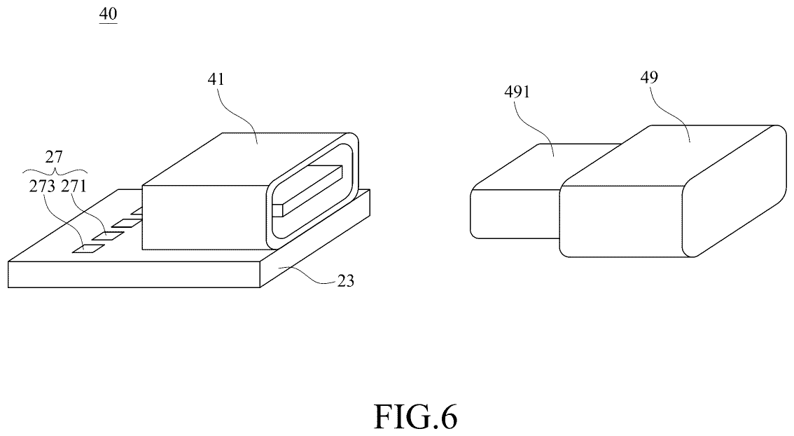

FIG. 6 is a perspective view of an electronic device according to another embodiment of the invention. Please referring to FIG. 2 and FIG. 3, the composite connector 40 includes a connector seat 41 and a carrier circuit board 23, wherein the connector seat 41 is disposed on the carrier circuit board 23.

In one embodiment of the invention, a connector seat 41 and a plurality of filtering units 251 are disposed on the first surface 231 of the carrier circuit board 23, while a plurality of second connection pins 27 are disposed on the second surface 233 of the carrier circuit board 23. The connector seat 41 can be connected to the second connection pins 27 via the filtering units 251. In other embodiments, a plurality of power filtering units 253 may be disposed on the first surface 231 of the carrier circuit board 23.

In one embodiment of the invention, the composite connector 40 may be installed on a housing of an electronic device, and a connector 491 of the expansion device 49 is able to insert into the connector seat 41 of the composite connector 40. For example, the composite connector 40 may be a USB connector on the electronic device, the connector 491 of the expansion device 49 may be a USB connector, and the expansion device 49 may be a USB flash drive, a network card, a sound card, or the like. After the expansion device 49 is connected to the composite connector 40 via the connector 491, the functions of the electronic device having the composite connector 40 can be expanded.

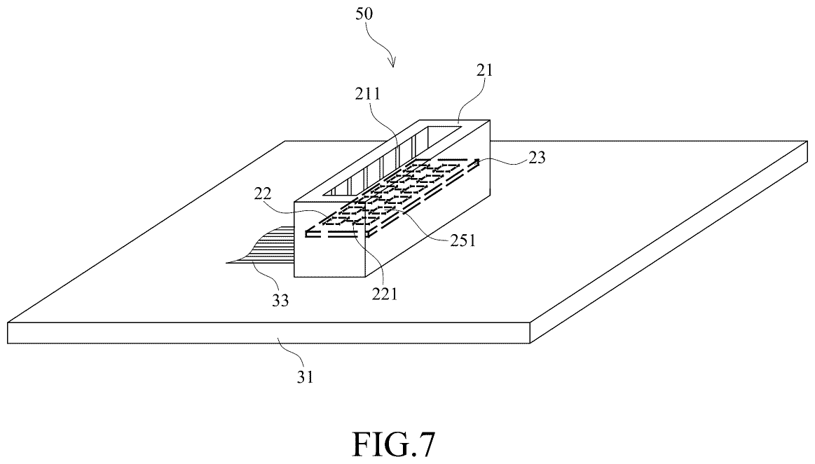

FIG. 7 is a perspective view of an electronic device according to another embodiment of the invention. The composite connector 50 includes a connector 21, a carrier circuit board 23, and a plurality of filtering units 251. The carrier circuit board 23 is located inside the connector 21, and the filtering units 251 are disposed on the carrier circuit board 23 and are also located inside the connector 21.

In this embodiment, the structure of the carrier circuit board 23 is similar to that of the carrier circuit board 23 shown in FIG. 2 and FIG. 3, with the main difference being that the area of the carrier circuit board 23 in this embodiment is smaller than or equal to the cross-sectional area of the connector 21 and is located inside the connector 21. The surface of the carrier circuit board 23 is provided with a plurality of first connection pins 22 and a plurality of second connection pins 27, while the transmission paths 235 are located on the surface and/or inside the carrier circuit board 23 and are used to connect the first connection pins 22 and the second connection pins 27.

Specifically, the filtering units 251 may be connected to part or all of the transmission paths 235, such that the filtering units 251 are located between the pins 211 of the connector 21 and the second connection pins 27 of the carrier circuit board 23. The first connection pins 22 of the carrier circuit board 23 are connected to the pins 211 of the connector 21, while the second connection pins 27 are used to connect to the transmission lines 33 of the main circuit board 31.

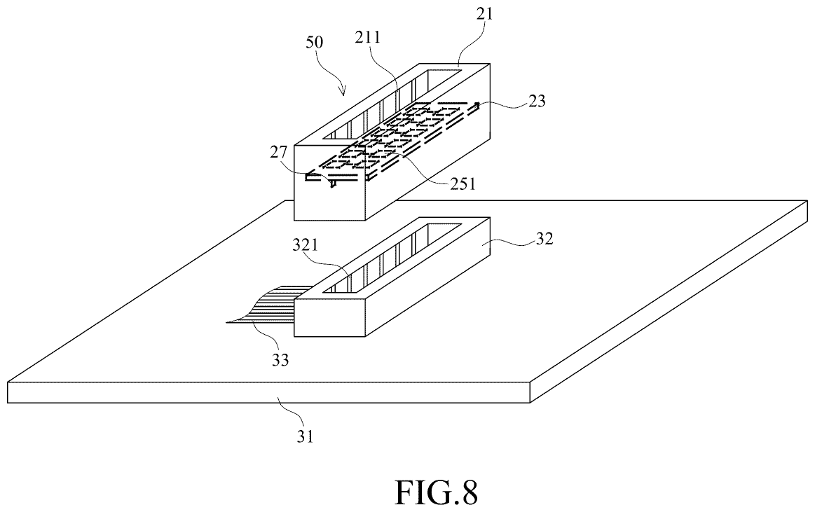

In the aforementioned embodiment of the invention, the composite connector 50 is directly disposed on the main circuit board 31, replacing the conventional connector seat on the carrier circuit board 23. In another embodiment of the invention, as shown in FIG. 8, the composite connector 50 is disposed on the main circuit board connector 32 of the main circuit board 31.

Specifically, the main circuit board 31 can be provided with a conventional main circuit board connector 32, and the second connection pins 27 of the composite connector 50 can be directly connected to the connection pins 321 of the main circuit board connector 32 on the main circuit board 31, such that the composite connector 50 is electrically connected to the transmission lines 33 on the main circuit board 31 via the main circuit board connector 32. In one embodiment of the invention, the composite connector 50 and the main circuit board connector 32 may have corresponding connectors. For example, the main circuit board connector 32 can be a female connector, and a male connector can be provided at the bottom of the composite connector 50. Thus, the composite connector 50 can be inserted into the main circuit board connector 32 through its own male connector to complete the connection between the composite connector 50 and the main circuit board connector 32.

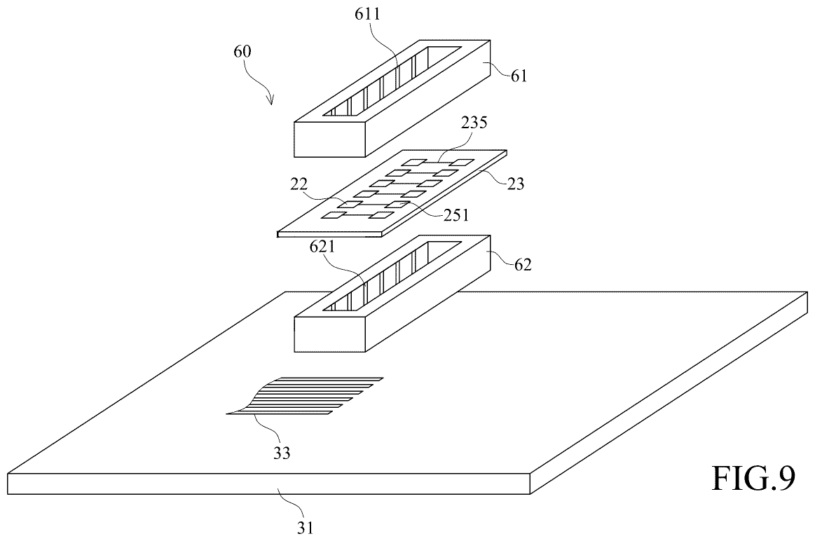

FIG. 9 is an exploded perspective view of a composite connector according to another embodiment of the invention. The composite connector 60 includes a first connector seat 61, a carrier circuit board 23, and a second connector seat 62. The first connector seat 61 and the second connector seat 62 are respectively disposed on different surfaces of the carrier circuit board 23, such as the upper and lower surfaces.

The first connector seat 61 is used to connect to an expansion card or an expansion device and includes multiple first pins 611. The second connector seat 62 is used to connect to the carrier circuit board 23 and a main circuit board 31, and includes multiple second pins 621.

Referring to FIG. 2 and FIG. 3, the carrier circuit board 23 may be planar and includes a first surface 231 and a second surface 233. The first connection pins 22 are disposed on the first surface 231 of the carrier circuit board 23, while the second connection pins 27 are disposed on the second surface 233 of the carrier circuit board 23.

The carrier circuit board 23 includes a plurality of transmission paths 235, and the first connection pins 22 are connected to the second connection pins 27 via the transmission path 235. For example, the transmission path 235 may be a transmission line or conductor disposed on the surface and/or inside the carrier circuit board 23.

The first connector seat 61 may include a plurality of first pins 611, and the first pins 611 are used to connect to the first connection pins 22 of the carrier circuit board 23. The second connector seat 62 may include a plurality of second pins 621, and the second pins 621 are used to connect to the second connection pins 27 of the carrier circuit board 23 and the transmission line 33 of the main circuit board 31. The first pins 611 of the first connector seat 61 are connected to the second pins 621 of the second connector seat 62 via the transmission paths 235 of the carrier circuit board 23.

At least one filtering unit 251 is disposed on the carrier circuit board 23, wherein part or all of the transmission paths 235 on the carrier circuit board 23 are connected to the filtering units 251. The filtering units 251 may be connected to part or all of the transmission paths 235, such that the filtering units 251 are located between part or all of the first pins 611 of the first connector seat 61 and part or all of the second pins 621 of the second connector seat 62.

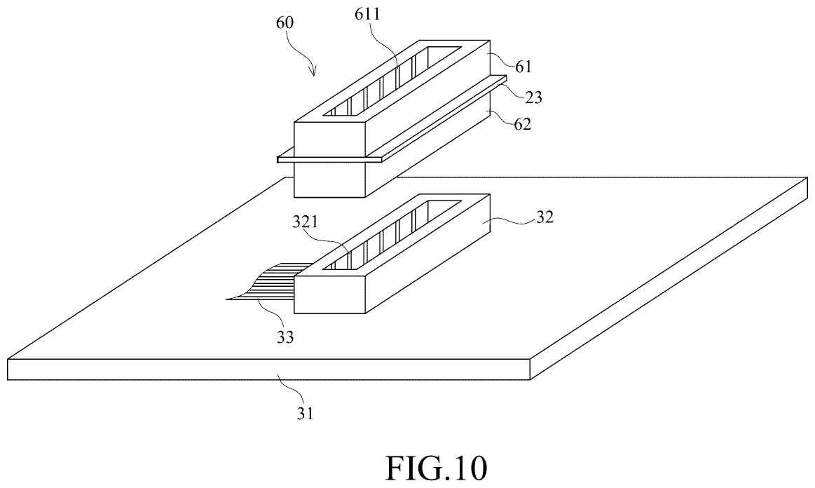

In the aforementioned embodiment of the invention, the second connector seat 62 of the composite connector 60 is directly disposed on the main circuit board 31, replacing the connector originally disposed on the carrier circuit board 23. In another embodiment of the invention, as shown in FIG. 10, the second connector seat 62 of the composite connector 60 is disposed on the main circuit board connector 32 of the main circuit board 31.

Specifically, the main circuit board 31 may be provided with a conventional main circuit board connector 32, and the second pins 621 of the second connector seat 62 of the composite connector 60 may be directly connected to the connection pins 321 of the main circuit board connector 32 of the main circuit board 31, such that the plurality of transmission lines 33 of the main circuit board 31 are connected to the transmission paths 235 of the carrier circuit board 23. In one embodiment of the invention, the second connector seat 62 of the composite connector 60 and the main circuit board connector 32 may be corresponding connectors. For example, the main circuit board connector 32 may be a female connector, and the second connector seat 62 of the composite connector 60 may be a male connector. The second connector seat 62 of the composite connector 60 can be inserted into the main circuit board connector 32 to complete the connection between the composite connector 60 and the main circuit board connector 32.

The foregoing descriptions are merely preferred embodiments of this disclosure, and are not intended to limit the scope of this disclosure, that is, all equivalent changes and modifications made according to shapes, structures, features and spirits described in the scope of the claims of this disclosure shall fall within the scope of the claims of this disclosure.

What is claimed is:

1. A composite connector, comprising:
a connector configured to connect to an expansion card or an expansion device, and including a plurality of pins;
a carrier circuit board including a plurality of surfaces and a plurality of transmission paths;
a plurality of first connection pins disposed on at least one of the surfaces of the carrier circuit board, and connected to the pins of the connector and the transmission paths of the carrier circuit board;
a plurality of second connection pins disposed on at least one of the surfaces of the carrier circuit board, and configured to connect to a plurality of transmission lines of a main circuit board and the transmission paths of the carrier circuit board; and
at least one filtering unit disposed on the carrier circuit board, wherein part or all of the transmission paths on the carrier circuit board are connected to the filtering unit.

2. The composite connector according to claim 1, wherein the main circuit board includes a main circuit board connector, the carrier circuit board is configured to connect to the main circuit board connector, and the transmission lines of the main circuit board are connected to the transmission paths of the carrier circuit board.

3. The composite connector according to claim 1, wherein the filtering unit comprises at least one band-stop filtering unit or at least one band-pass filtering unit.

4. The composite connector according to claim 1, wherein the filtering unit is configured to block or absorb common-mode noise at specific frequencies.

5. The composite connector according to claim 1, wherein the first connection pins and the second connection pins include at least one signal connection pin and a plurality of power connection pins.

6. The composite connector according to claim 5, further comprising at least one power filtering unit connected to the power connection pin, and the power filtering unit comprising a capacitor, an inductor, a diode, or a transistor.

7. The composite connector according to claim 5, wherein the filtering unit is connected to the signal connection pins, and the filtering unit comprising a capacitor, an inductor, a diode, or a transistor.

8. The composite connector according to claim 1, wherein the carrier circuit board includes at least one signal delay structure configured to connect part or all of the transmission paths, and delay of the transmission path passing through the signal delay structure is synchronized with or maintained at a specific delay relative to at least one other transmission path.

9. The composite connector according to claim 1, wherein the filtering unit is formed by at least one metal layer located on or within the carrier circuit board.

10. The composite connector according to claim 1, wherein the filtering unit is a passive component.

11. A composite connector comprising:
a connector for connecting to an expansion card or an expansion device, and including a plurality of pins;
a carrier circuit board disposed inside the connector and including a plurality of surfaces and a plurality of transmission paths;
a plurality of first connection pins disposed on at least one of the surfaces of the carrier circuit board, and connected to the pins of the connector and the transmission paths of the carrier circuit board;
a plurality of second connection pins disposed on at least one of the surfaces of the carrier circuit board, and connected to part of the pins of the connector and the transmission paths of the carrier circuit board; and
at least one filtering unit disposed on the carrier circuit board, wherein part or all of the transmission paths on the carrier circuit board are connected to the filtering unit.

12. The composite connector according to claim 11, wherein the main circuit board includes a main circuit board connector, the carrier circuit board is configured to connect to the main circuit board connector, and the transmission lines of the main circuit board are connected to the transmission paths of the carrier circuit board.

13. The composite connector according to claim 11, wherein the filtering unit comprises at least one band-stop filtering unit or at least one band-pass filtering unit.

14. The composite connector according to claim 11, wherein the filtering unit is configured to block or absorb common-mode noise at specific frequencies.

15. A composite connector, comprising:
a first connector for connecting to an expansion card or an expansion device, and including a plurality of first pins;
a carrier circuit board including a plurality of surfaces and a plurality of transmission paths;
a plurality of first connection pins disposed on at least one of the surfaces of the carrier circuit board, and connected to the first pins of the first connector and the transmission paths of the carrier circuit board;
a plurality of second connection pins disposed on at least one of the surfaces of the carrier circuit board;
a second connector including a plurality of second pins for connecting to the second connection pins of the carrier circuit board and a plurality of transmission lines of a main circuit board; and
at least one filtering unit disposed on the carrier circuit board, wherein part or all of the transmission paths on the carrier circuit board are connected to the filtering unit.

16. The composite connector according to claim 15, wherein the main circuit board includes a main circuit board connector, and the second pins of the second connector are connect to a plurality of connection pins of the main circuit board connector, thereby connecting the plurality of transmission lines of the main circuit board to the transmission paths of the carrier circuit board.

17. The composite connector according to claim 15, wherein the filtering unit comprises at least one band-stop filtering unit or at least one band-pass filtering unit.

18. The composite connector according to claim 15, wherein the filtering unit is configured to block or absorb common-mode noise at specific frequencies.
